(19) United States
(12) Patent Application Publication
(10) Pub. No.: US 2015/0137251 A1
(43) Pub. Date: May 21, 2015

(54) SEMICONDUCTOR DEVICE AND METHOD OF MANUFACTURING THE SAME

(71) Applicant: SAMSUNG ELECTRONICS CO., LTD., Suwon-si (KR)

(72) Inventors: SUNGHEE LEE, OSAN-SI (KR); EUI-CHUL JEONG, YONGIN-SI (KR); NARA KIM, SEONGNAM-SI (KR); SEUNG HWAN KIM, HWASEONG-SI (KR); DONGWOO WOO, SEOUL (KR); SANGHOON LEE, SEONGNAM-SI (KR); SUNGJOO LEE, SEOUL (KR)

(21) Appl. No.: 14/454,476

(22) Filed: Aug. 7, 2014

(30) Foreign Application Priority Data
Nov. 19, 2013 (KR) 10-2013-0140678

(51) Int. Cl. H01L 29/06; H01L 29/78; H01L 21/02; H01L 29/423; H01L 27/108; H01L 21/762

(52) U.S. Cl. CPC H01L 29/0653; H01L 27/108; H01L 21/76224; H01L 21/02164; H01L 21/0223; H01L 21/02178; H01L 21/02181; H01L 21/02189; H01L 21/0228; H01L 21/02263; H01L 29/4238; H01L 29/7846
USPC 257/368; 438/296

(57) ABSTRACT

A semiconductor device includes a substrate and a device isolation pattern extending from a surface of the substrate into the substrate. The device isolation pattern has an electrically negative property and a physically tensile property. The device isolation pattern delimits an active region of the substrate. A transistor is provided at the active region and has a channel region formed by part of the active region.

### PRIORITY STATEMENT

This U.S. non-provisional patent application claims priority under 35 U.S.C. §119 to Korean Patent Application No. 10-2013-0140678, filed on Nov. 19, 2013, in the Korean Intellectual Property Office, the disclosure of which is hereby incorporated by reference in its entirety.

### BACKGROUND

The inventive concept relate to semiconductor devices and to methods of manufacturing the same. More particularly, the inventive concept relate to dynamic random access memory (DRAM) devices and to methods of manufacturing the same.

Semiconductor devices are widely used in the field of electronics because of their small size, multi-functionality and/or low manufacture costs. Semiconductor devices may be categorized as memory devices for storing data, logic devices for processing data, and hybrid devices having both the function of the semiconductor memory devices and the function of the semiconductor logic devices.

Highly integrated semiconductor devices have been increasingly in demand to advance the development of the electronics industry. However, increasing the degree of integration of semiconductor devices has given rise to various challenges. For example, it becomes more difficult to secure the necessary process margin of an exposure process used to form patterns of a typical semiconductor device, such as circuit patterns, as the patterns become finer and finer.

Likewise, the demand for semiconductor devices which operate at higher speeds has increased in connection with the developing of new electronic products. However, various challenges arise when trying to produce a semiconductor device that satisfies both of the above demands, namely, high degrees of integration and high speed operation.

### SUMMARY

Embodiments of the inventive concept may provide highly integrated semiconductor devices.

Embodiments of the inventive concept may provide methods of manufacturing the highly integrated semiconductor device.

According to one aspect of the inventive concept, there is provided a semiconductor device including a device isolation pattern extending from a surface of the substrate into the substrate, and in which the device isolation pattern is net electrically negative, and there is net stress in the device isolation pattern that is tensile.

According to another aspect of the inventive concept, there is provided a semiconductor device including a substrate comprising semiconductor material, a device isolation pattern extending in the substrate and delimiting at least one active region of the semiconductor material, and a transistor situated at the active region, and in which the transistor has a channel region constituted by part of the active region, and there is net stress in the device isolation pattern that is tensile, net stress in the active region that is compressive, and the device isolation pattern is net electrically negative. According to still another aspect of the inventive concept, there is provided a method of manufacturing a semiconductor device including forming a trench in a substrate, conformally forming silicon oxide on the substrate including along surfaces defining the trench, whereby a portion of the trench remains unfilled, and forming metal oxide in the portion of the trench that remains unfilled after the silicon oxide has been formed, thereby forming a device isolation pattern.

### BRIEF DESCRIPTION OF THE DRAWINGS

The inventive concept will become more apparent in view of the attached drawings and accompanying detailed description.

FIG. 1A is a plan view of a semiconductor device according to the inventive concept;

FIG. 1B is a cross-sectional view taken along a line I-I′ of FIG. 1A;

FIGS. 2A through 7B illustrate a method of manufacturing a semiconductor device according to the inventive concept, in which FIGS. 2A, 3A, 4A, 5A, 6A and 7A are each a plan view of the device during the course of its manufacture, and FIGS. 2B, 3B, 4B, 5B, 6B and 7B are cross-sectional views taken along lines I-I′ of FIGS. 2A, 3A, 4A, 5A, 6A and 7A, respectively;

FIG. 8A is a graph illustrating currents and body effects of an isolation patterns of a semiconductor device according to the inventive concept and of examples 1 and 2 for comparison;

FIG. 8B is a graph illustrating energy band barriers of DRAM devices including device isolation patterns, according to the inventive concept and examples 1 and 2 for comparison, at digital signals of ‘0’ and ‘1’;

FIG. 9A is a schematic block diagram of a memory card employing a semiconductor device according to the inventive concept; and

FIG. 9B is a schematic block diagram of an information processing system employing a semiconductor device according to the inventive concept.

### DETAILED DESCRIPTION OF THE PREFERRED EMBODIMENTS

Various embodiments and examples of embodiments of the inventive concept will be described more fully hereinafter with reference to the accompanying drawings. In the drawings, the sizes and relative sizes and shapes of elements, layers and regions, such as implanted regions, shown in section may be exaggerated for clarity. In particular, the cross-sectional illustrations of the semiconductor devices and intermediate structures fabricated during the course of their manufacture are schematic. Also, like numerals are used to designate like elements throughout the drawings.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. Also, when a feature is described as “extending” or “elongated” in a particular direction, it will be understood that the direction coincides with a major dimension of the feature such as its length as the figures will make clear.

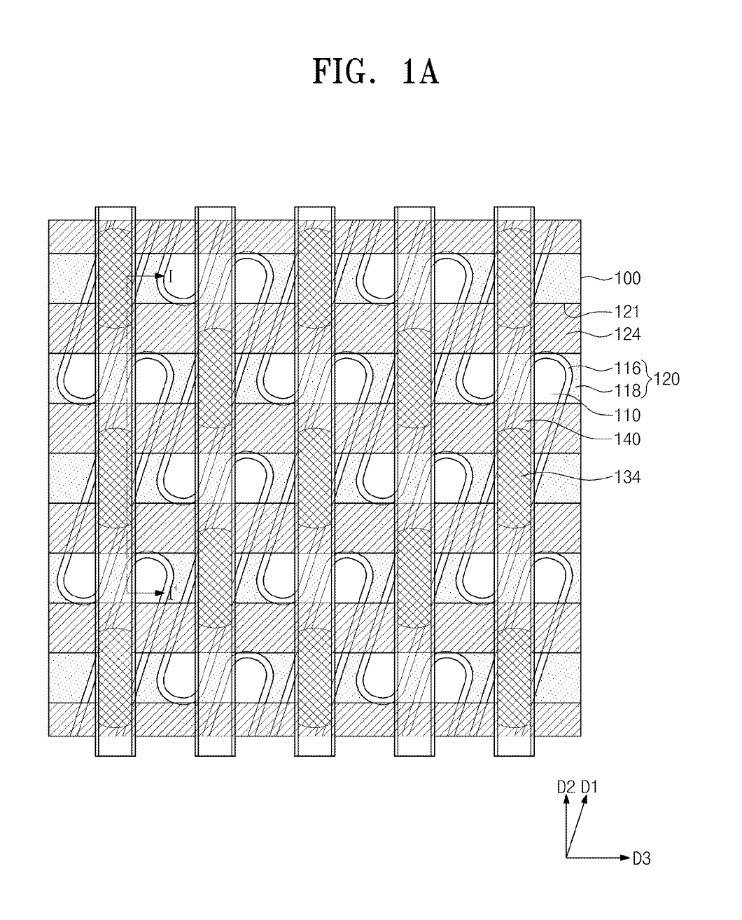

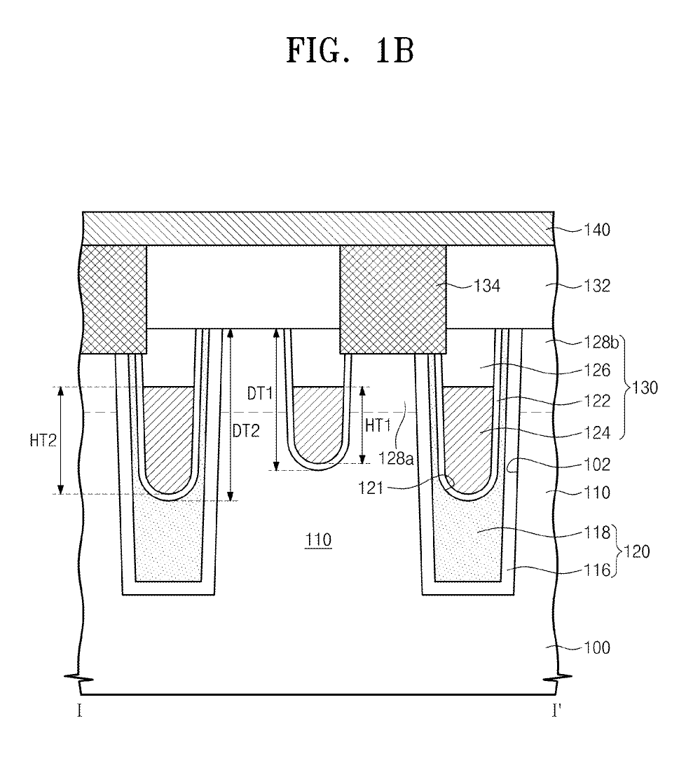

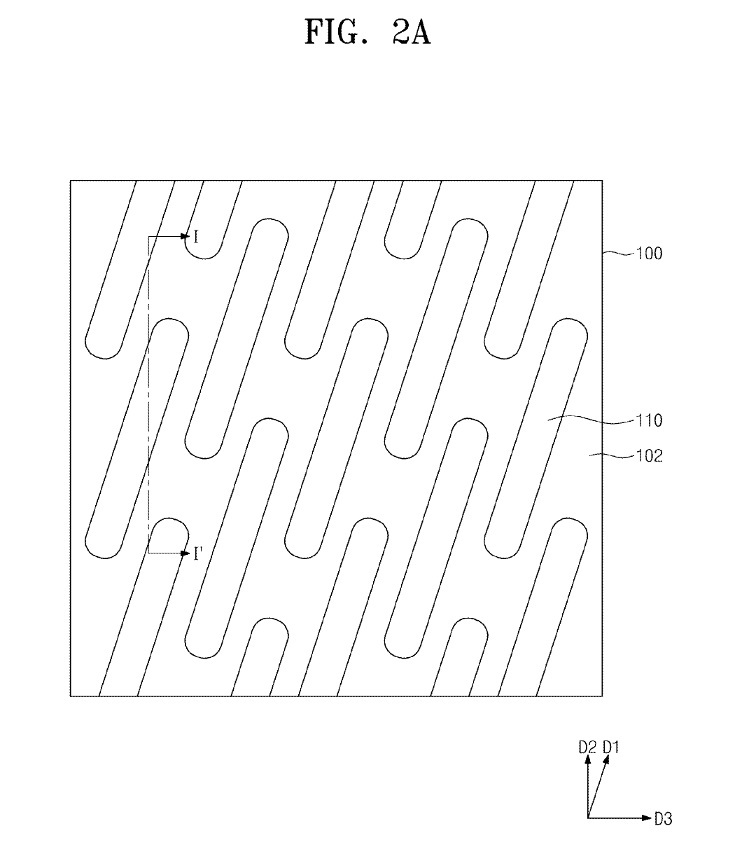

A semiconductor device according to the inventive concept will now be described in more detail with reference to FIG. 1A and FIG. 1B.

The semiconductor device includes a device isolation pattern 120, a transistor 130, and a bit line 140 on a substrate 100.

The substrate 100 may be a semiconductor substrate including at least one of silicon and germanium. For example, the substrate 100 may be a bulk silicon substrate. The substrate 100 has active regions 110 defined by the device isolation pattern 120. The device isolation pattern 120 may extend from a surface of the substrate 100 into the substrate 100.

The active regions 110 may be elongated in a first direction D1, e.g.,, may each have the shape of an ellipse as viewed in plan and whose long axis extends in direction D1. The active regions 110 may be spaced apart from each other in the first direction D1 and a second direction D2 different from the first direction D1. However, the inventive concept is not limited to active regions 110 having the shapes and arrayed as illustrated in FIGS. 1A and 1B.

The device isolation pattern 120 may be formed of insulating material occupying a trench 102 in the substrate 100. According to this embodiment of the inventive concept, the device isolation pattern 120 has a multi-layered structure. In one example of this embodiment, the device isolation pattern 120 includes a silicon oxide layer 116 and a metal oxide layer 118. In this case, the silicon oxide layer 116 may be in contact with the active regions 110, and the metal oxide layer 118 may fill a remainder of the trench 120, with the silicon oxide layer 116 interposed between the metal oxide layer 118 and the active regions 110. The metal oxide layer 118 may include at least one of a hafnium oxide (HfOₓ) layer, an aluminum oxide (AlOₓ) layer, and a zirconium oxide (ZrOₓ) layer.

Electrical/physical properties of materials of such a device isolation pattern can affect an on-current characteristic and a body-effect characteristic of a transistor at an active region of a substrate delimited by the device isolation pattern. For example, a silicon nitride layer may have an electrically positive property and a physically compressive property. Thus, a silicon nitride layer when constituting a device isolation pattern may provide a substrate with a tensile property. In contrast, a silicon oxide layer may have an electrically neutral property and a physically tensile property, so as to provide the substrate with a compressive property.

In one example of this embodiment according to the inventive concept, the metal oxide layer 118 has an electrical negative property and a physically tensile property greater than that of the silicon oxide layer 116. Thus, the substrate 100 may be provided with a relatively great compressive property. As a result of the device isolation pattern 120 having an electrically negative property and the substrate 100 (active region 110) having a relatively great compressive property, the transistor 130 may have a great body effect and, in turn, a relatively high potential barrier. Thus, the transistor 130 has an improved on-current characteristic.

Also, according to an aspect of the inventive concept, if the metal oxide layer 118 were in contact with the substrate 100, trap sites could be generated between the metal oxide layer 118 and the substrate 100. A leakage current may occur through the trap sites. According to this embodiment of the inventive concept, though, there are no such trap sites because silicon oxide layer 116 is interposed between the substrate 100 and the metal oxide layer 118. Thus, leakage current is prevented.

The substrate 100 may include recesses 121 in the top surface of the substrate 100. Additionally, the recesses 121 may extend in a third direction D3 different from the lengthwise direction of the active regions 110 (i.e., the first direction), as illustrated in FIGS. 1A and 1B. For example, the third direction D3 may be perpendicular to the second direction D2. The recesses 121 may be spaced apart from each other in the second direction D2.

Each of the recesses 121 may cross several active regions 110 and the device isolation pattern 120 between adjacent ones of the active regions 110. In this embodiment, the recess 121 has a first depth DT1 in the active region 110, and a second depth DT2 in the device isolation pattern 120 greater than the first depth DT1.

The transistor 130 may include a gate insulating layer 122, a gate electrode 124, a first dopant region 128a, and a second dopant region 128b. The gate electrode 124 may fill a lower region of the recess 121 and may extend in the third direction D3. In this embodiment, the gate electrode 124 has a first height HT1 in the active region 110, and the gate electrode 124 has a second height HT2 in the device isolation pattern 120 greater than the first height HT1. The gate electrode 124 may include at least one of, for example, doped poly-silicon and a metal (e.g., tungsten).

The gate insulating layer 122 is disposed between the substrate 100 and the gate electrode 124. In the illustrated example of this embodiment, the gate insulating layer 122 extends along the surfaces delimiting the recesses 121. The gate insulating layer 122 may include an oxide.

The transistor 130 may further include a capping pattern 126 filling an upper region of the recess 121 on the gate electrode 124. The capping pattern 126 may include an insulating material such as a nitride.

The first and second dopant regions 128a and 128b are disposed in the active region 110 at both sides of the gate electrode 124, respectively. In an example of this embodiment, the first dopant region 128a is disposed in a central portion of the active region 110, and the second dopant region 128b is disposed in an edge portion of the active region 110.

The first dopant region 128a may be electrically connected to the bit line 140 through a first contact plug 134. The bit line 140 may extend in the second direction D2.

Although not shown in the drawings, the second dopant region 128b may be electrically connected to a capacitor (not shown) through a second contact plug (not shown).

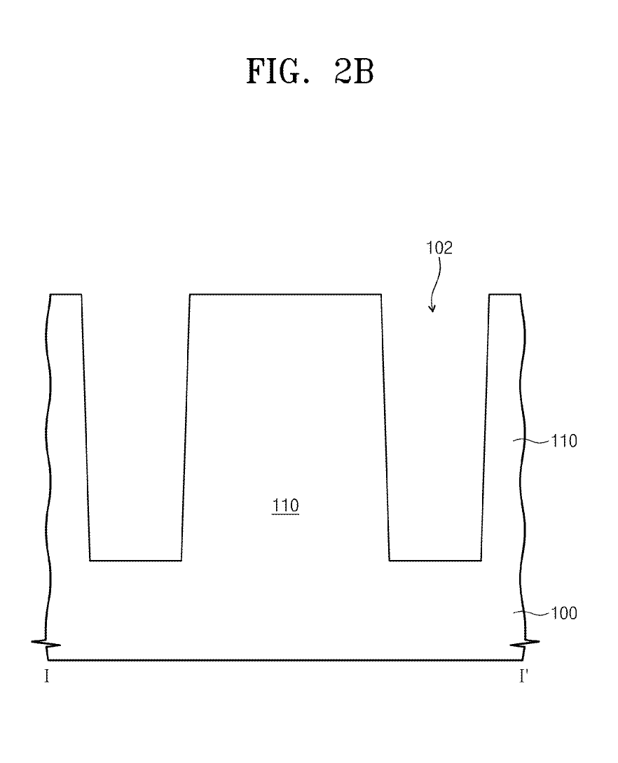

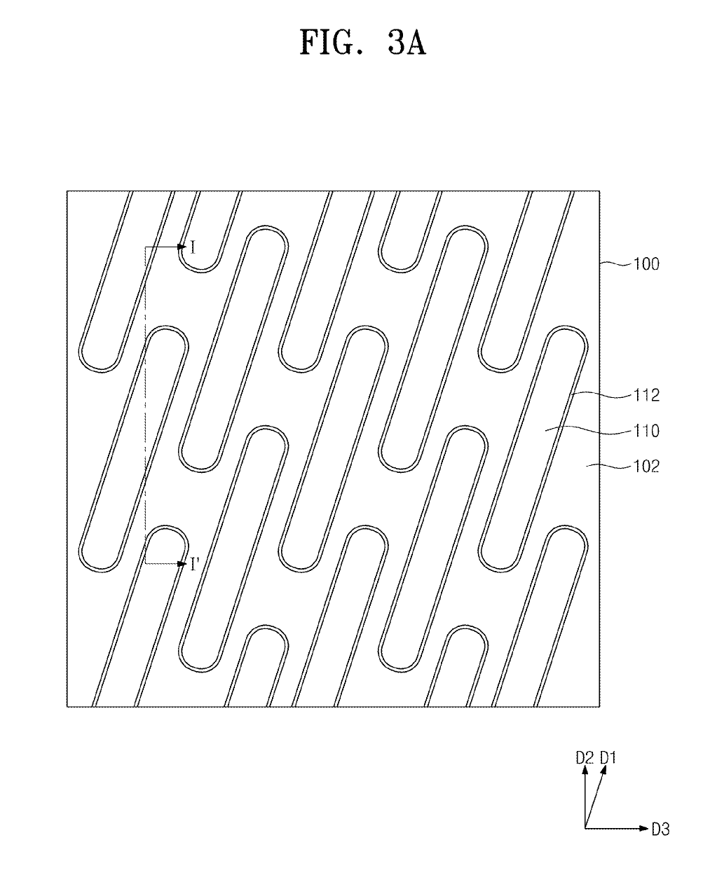

A method of manufacturing a semiconductor device according to the inventive concept will now be described in detail with reference to FIGS. 2A through 7B.

Referring to FIGS. 2A and 2B, a trench 102 is formed in a substrate 100.

For example, a first mask is formed on the substrate 100, and the substrate 100 is then etched using the first mask as a etch mask to form the trench 102. In some cases, the width of the trench 102 may progressively decrease toward the bottom of the trench 102 as a result of the etching process.

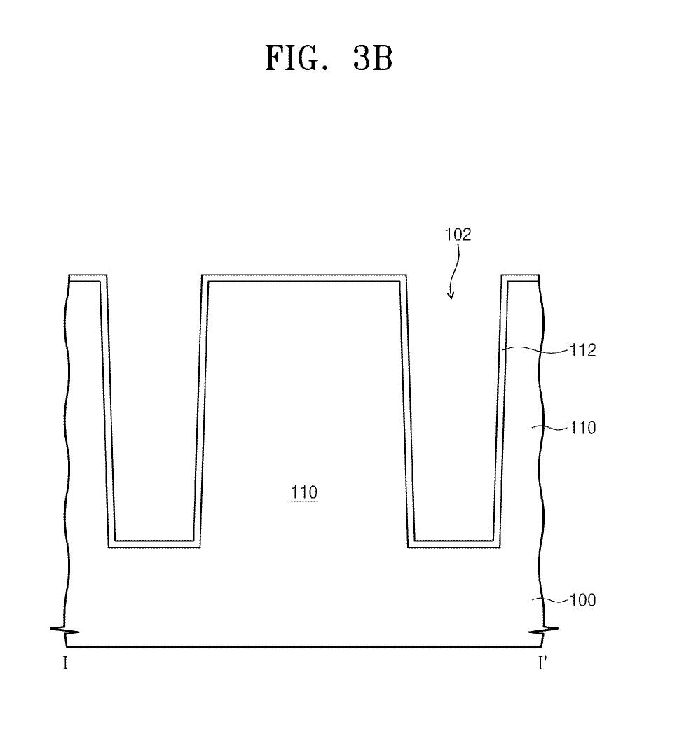

Referring to FIGS. 3A and 3B, a first silicon oxide layer 112 is conformally formed on the substrate 100 including within the trench 102. The first silicon oxide layer 112 may be formed by a radical oxidation process or an atomic layer deposition (ALD) process.

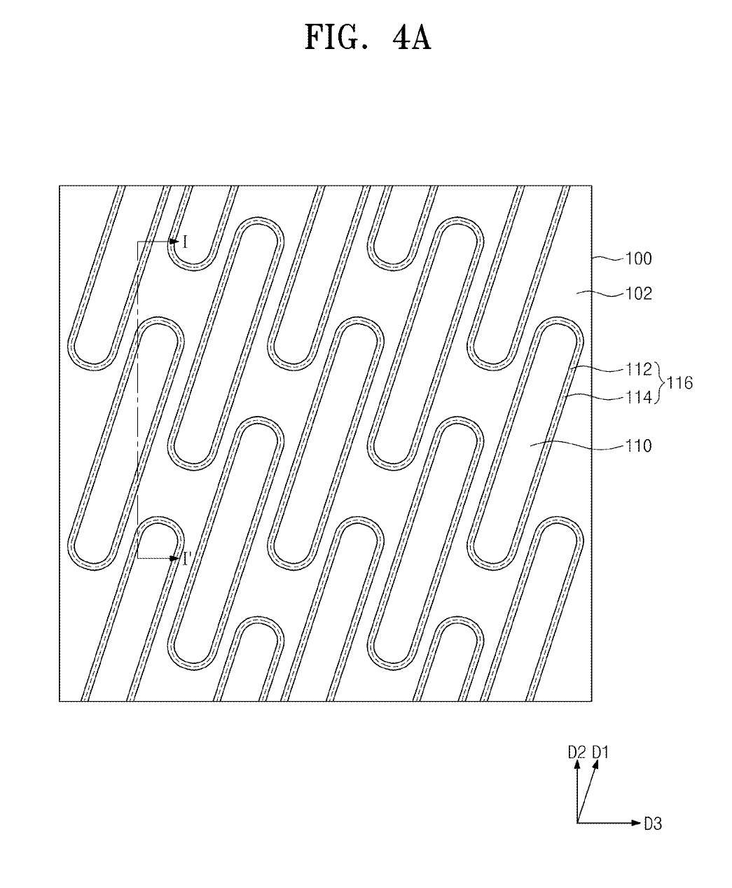

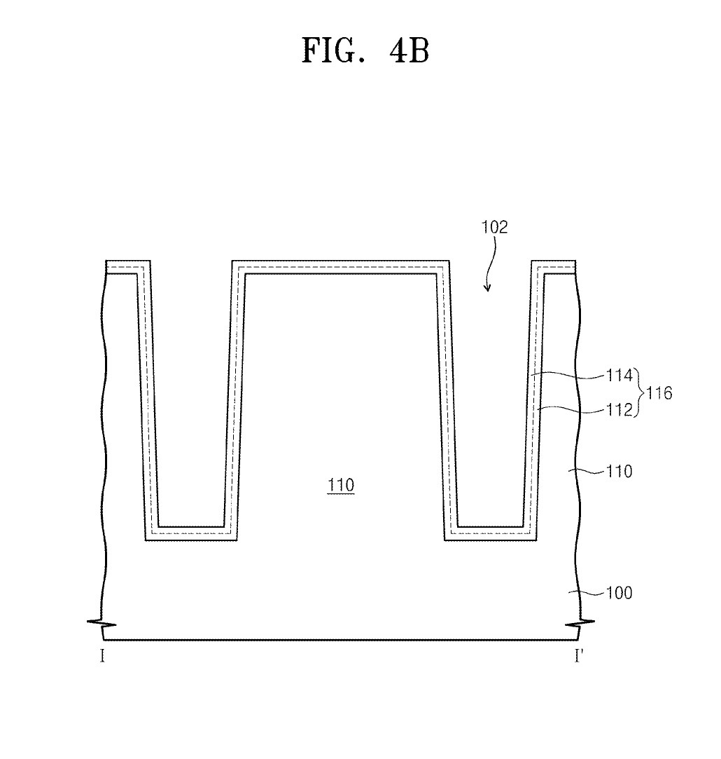

Referring to FIGS. 4A and 4B, a second silicon oxide layer 114 is conformally formed on the substrate 114 having the first silicon oxide layer 112. The second silicon oxide layer 114 may be formed by a low-pressure deposition process or an atomic layer deposition process. The second silicon oxide layer 114 may be a middle temperature oxide (MTO) layer.

In one example of this embodiment, the first silicon oxide layer 112 and the second silicon oxide layer 114 are formed in-situ. In some cases, an interface may not be discernible between the first and second silicon oxide layers 112 and 114. Alternatively, i.e., instead of the first and second silicon oxide layers 112 and 114, only one silicon oxide layer is formed by the atomic layer deposition process. In any case, it may be considered that a silicon oxide layer 116 is formed.

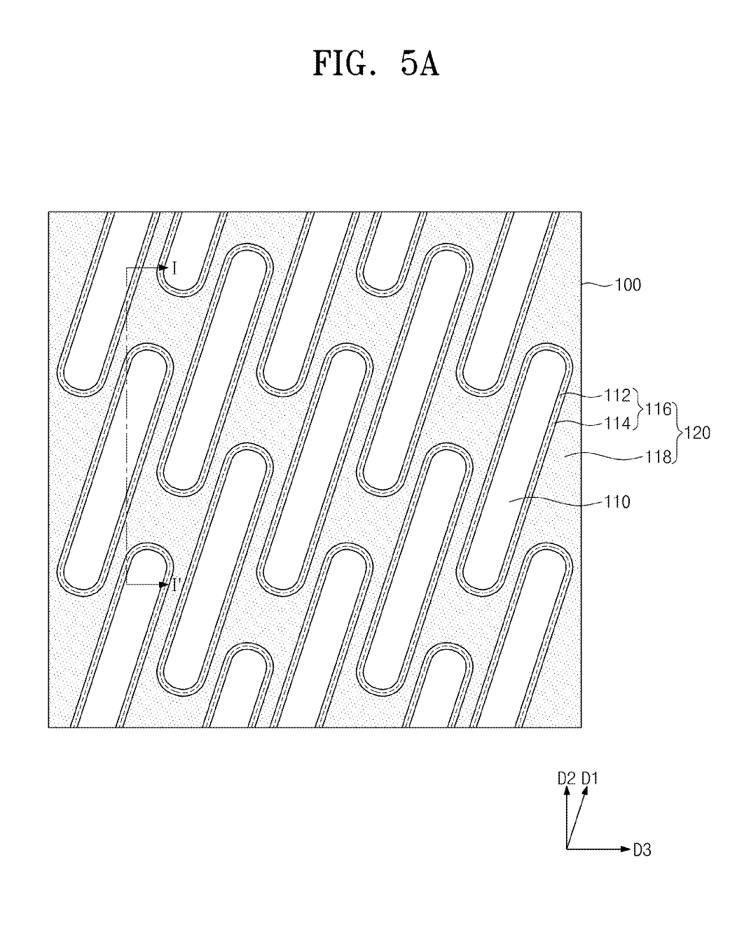

Referring to FIGS. 5A and 5B, a metal oxide layer 118 is formed to fill a remainder of the trench 102, i.e., is formed on the first and second silicon oxide layers 112 and 114 in the trench 102.

The metal oxide layer 118 may be formed by an atomic layer deposition process. The metal oxide layer 118 may include at least one of hafnium oxide (HfOₓ), aluminum oxide (AlOₓ) layer, and zirconium oxide (ZrOₓ).

The metal oxide layer 118 and the first and second silicon oxide layers 112 and 114 may be planarized until a top surface of the substrate 100 is exposed, thereby forming a device isolation pattern 120. The planarization process may be a chemical mechanical polishing (CMP) process or an etch-back process.

A plurality of active regions 110 may be defined by the device isolation pattern 120 as a result. Each of the active regions 110 may have the shape of an ellipse, as viewed in plan, whose long axis is parallel to a first direction Dl.

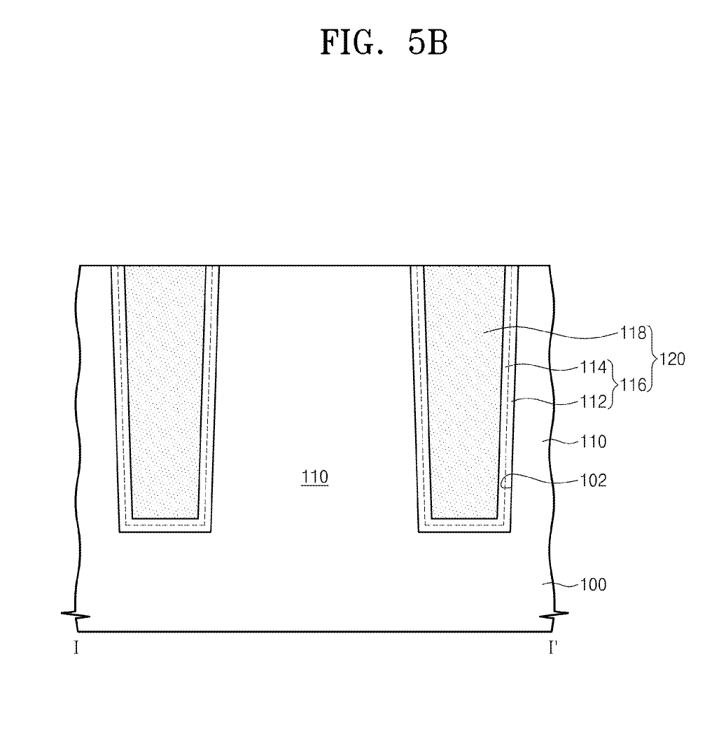

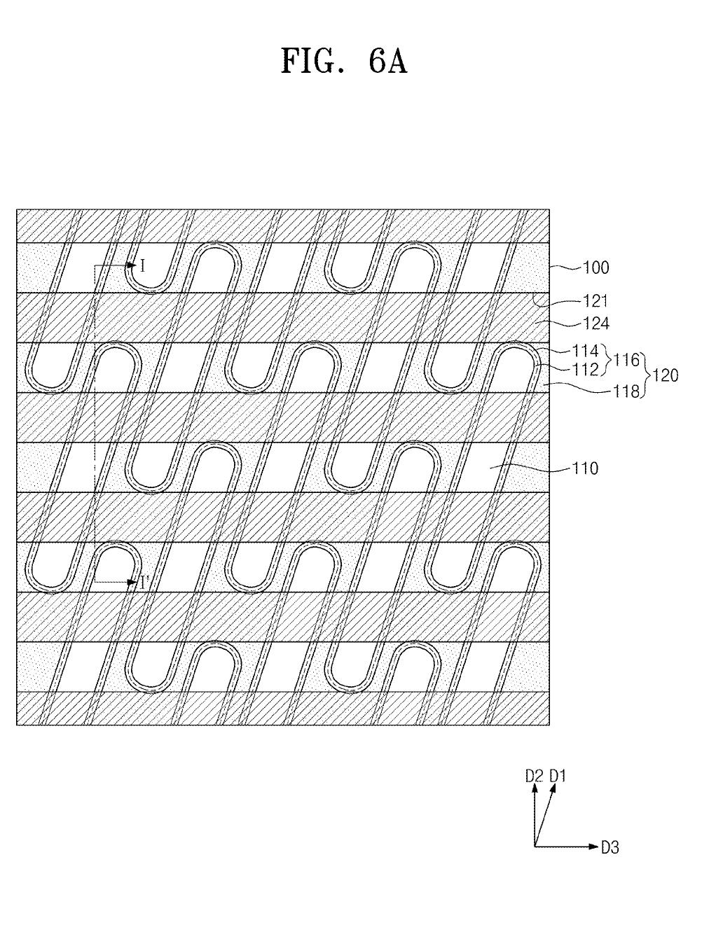

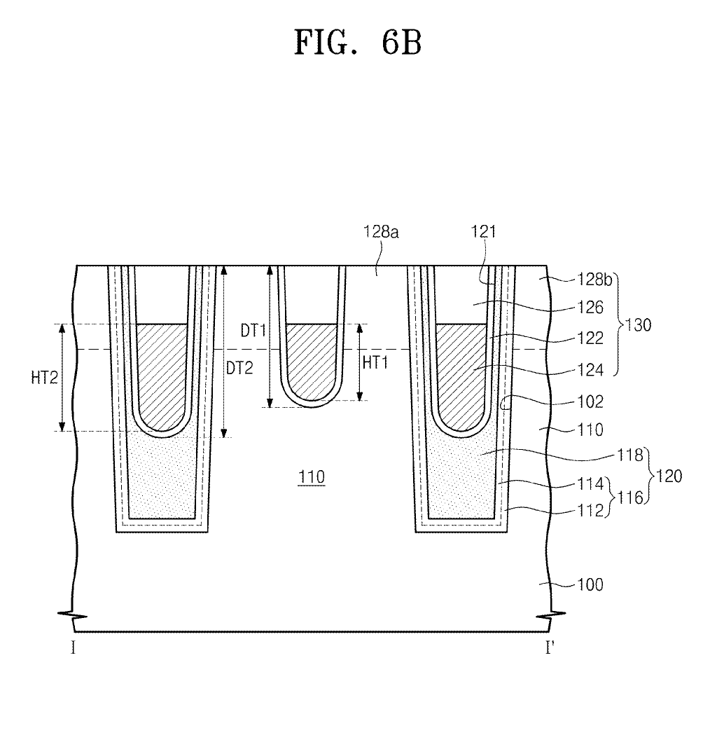

Referring to FIGS. 6A and 6B, a transistor 130 is formed on the substrate 100.

For example, recesses 121 extending longitudinally in a third direction D3 are formed in the substrate 100 by an etch process. The recesses 121 may be spaced apart from each other in a second direction D2. The recesses 121 may be parallel to each other. The recesses 121 may be formed to cross several active regions 110 and the device isolation pattern 120 between/adjacent the active regions 110. The active regions 110 are formed of semiconductor material (e.g., silicon or germanium), and the device isolation pattern 120 includes the silicon oxide and the metal oxide, as described above. Thus, the process used to form the recesses 121, e.g., an etch process, may form the recess 121 in the active region 110 to a first depth DT1, and may form the recess 121 in the device isolation pattern 120 to a second depth DT2 greater than the first depth DT1 because of different etch rates between the material of the active regions 110 and the material of the device isolation pattern 120.

A gate insulating layer 122 is formed along inner surfaces of the resultant structure which define the recesses 121. The gate insulating layer 122 may be formed by a thermal oxidation process. At this time, if the active regions 110 include silicon, the gate insulating layer 122 may include a silicon oxide layer. The gate insulating layer 122 does not completely fill the recesses 121.

Gate electrodes 124 may be formed to fill lower regions of the recesses 121 having the gate insulating layer 122. Each of the gate electrodes 124 may be formed of at least one material selected from the group consisting of doped poly-silicon and metals (e.g., tungsten).

Capping patterns 126 may be formed to fill upper regions of the recesses 121 on the gate electrodes 124, respectively. The capping patterns 126 may be formed of an insulating material such as a nitride.

Dopants may then be injected into the active regions 110 exposed at both sides of the gate electrodes 124 to form first dopant regions 128a and second dopant regions 128b. The first dopant region 128a and the second dopant region 128b may function as a first source/drain region and a second source/drain region of the transistor 130, respectively. In some cases, the first dopant region 128a may be formed in a central portion of the active region 110, and the second dopant region 128b may be formed in an edge portion of the active region 110.

As described above, the device isolation pattern 120 includes metal oxide layer 118. Therefore, the device isolation pattern 120 has an electrically negative property, and the active regions 110 of the substrate 100 have a compressive property.

Thus, the completed transistor 130 may have an improved on-current characteristic, and the body effect of the transistor 130 is increased such that a potential barrier is higher.

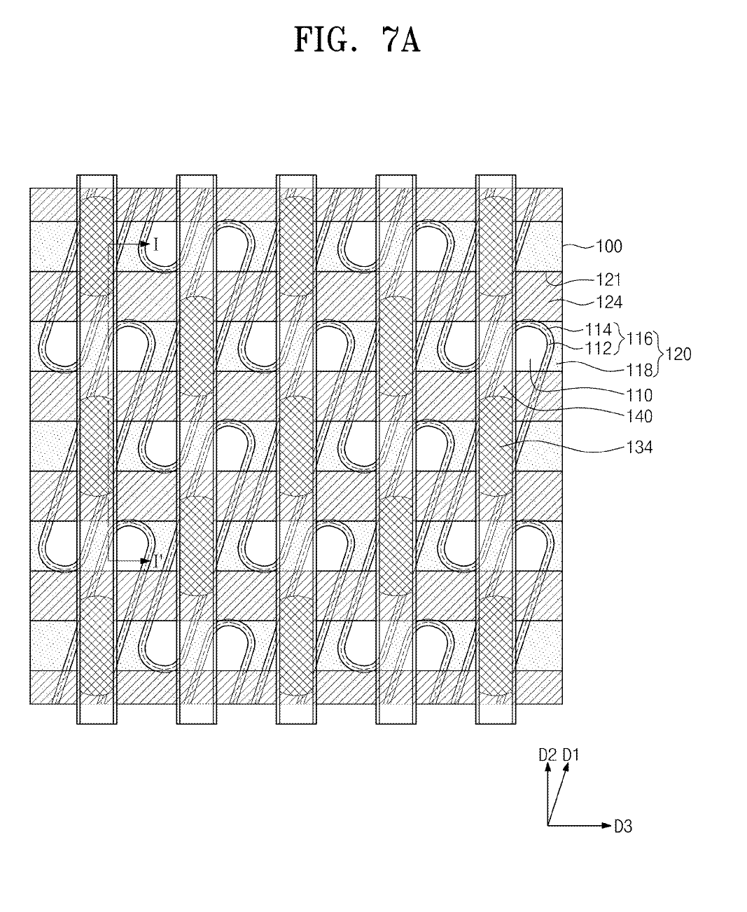

Referring to FIGS. 7A and 7B, a bit line 140 may be formed to be electrically connected to the first dopant region 128a.

For example, an interlayer insulating layer 132 is formed on the substrate 100 having the transistor 130. The interlayer insulating layer 132 may be formed of an insulating material such as an oxide. The interlayer insulating layer 132 is patterned to form a contact hole exposing the first dopant region 128a. The contact hole may be filled with a conductive material, thereby forming a first contact plug 134. The bit line 140 extending in the second direction D2 may be formed on the first contact plug 134 and the interlayer insulating layer 132. The bit line 140 may be electrically connected to the first dopant region 128a through the first contact plug 134.

Although not shown in the drawings, the second dopant region 128b may be electrically connected to a capacitor through a second contact plug.

The following simulations were carried out to confirm effects and advantages of the inventive concept.

As representative of the inventive concept, a device isolation pattern including a first silicon oxide layer, a second silicon oxide, and a hafnium oxide layer was used. A device isolation pattern of a first example for comparison with that according to the inventive concept, namely example 1, included first, second and third silicon oxide layers formed by atomic layer deposition processes. A device isolation pattern of a second example for comparison, namely, example 2, included first and second silicon oxide layer and a silicon nitride layer.

The following table 1 shows physical properties and electrical properties of structures and layers of the device isolation patterns of the embodiment and the first and second examples (comparison examples 1 and 2).

TABLE 1

| | | | Comparison | Comparison |
|---|---|---|---|---|
| | | embodiment | example 1 | example 2 |
| Electrical property | | −1E12 | 0 | +1E12 |
| [C/cm²] | | | | |
| Physical | First | Tensile (−) | Tensile (−) | Tensile (−) |
| property | layer | | | |
| | Second | Tensile (−) | Tensile (−) | Tensile (−) |
| | layer | | | |
| | Third | More tensile (−−) | Tensile (−) | Compressive (+) |
| | layer | | | |

| | | | |
|---|---|---|---|
| Density of electron | 1.5E−10 | 4.5E−7 | 3.5E−4 |
| flow [A/cm²] | | | |

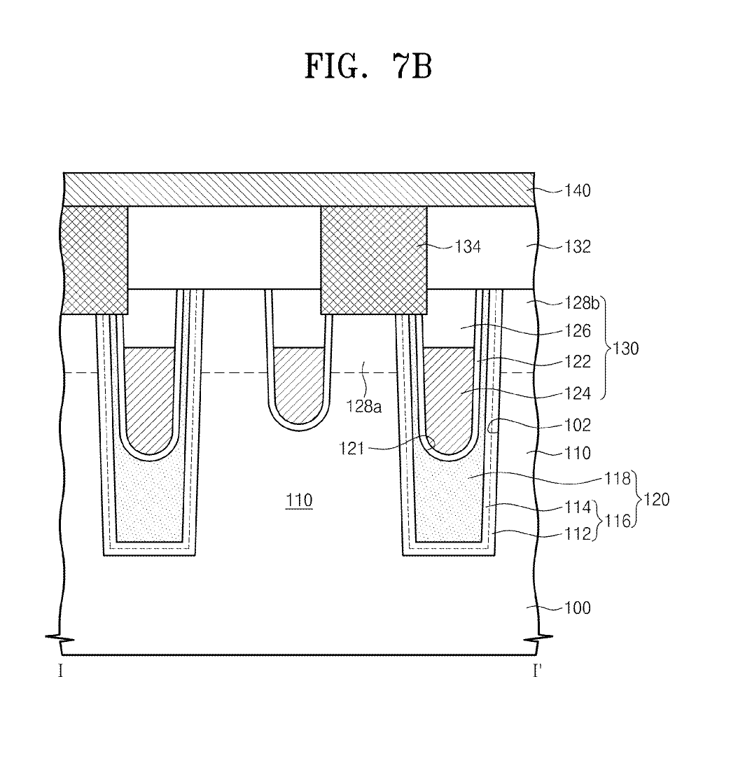

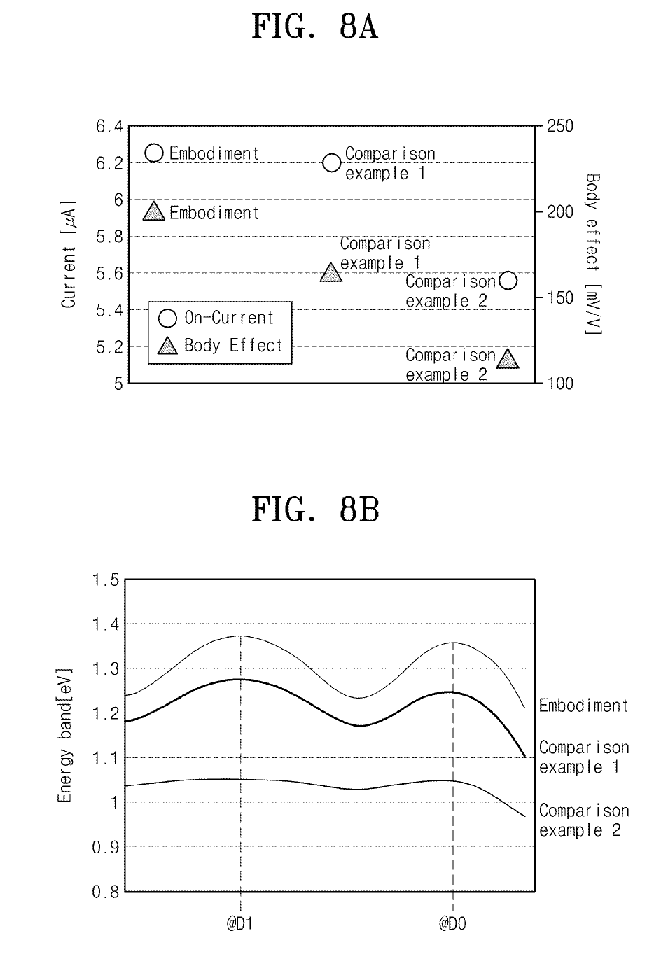

FIG. 8A is a graph illustrating currents and body effects of a device isolation pattern for the embodiment representative of inventive concept and for devices isolation patterns of the examples 1 and 2.

Referring to FIG. 8A, the body effect of the embodiment is about 200 mV/V. In other words, the body effect of the embodiment is greater, i.e., is better, than the body effects of the examples 1 and 2. Thus, the on-current of the embodiment is greater than those of the comparison examples 1 and 2.

FIG. 8B is a graph illustrating energy band bathers of an embodiment of a DRAM device according to the inventive concept, and examples 1 and 2 of DRAM devices, having the respective device isolation patterns described above with reference to Table 1.

The following table 2 shows the energy band bathers at digital signals of ‘0’ and ‘1’ for the embodiment, the comparison example 1, and the comparison example 2.

TABLE 2

| | | Comparison | Comparison |
|---|---|---|---|
| | Embodiment | example 1 | example 2 |
| Energy band barrier | 0.133 eV | 0.092 eV | 0.014 eV |
| @ digital signal 1 | | | |
| Energy band barrier | 0.144 eV | 0.139 eV | 0.082 eV |
| @ digital signal 0 | | | |

Referring to FIG. 8B and the table 2, the energy band bathers of a DRAM device according to the inventive concept are greater than those of the comparison examples 1 and 2 at the digital signals ‘1’ and ‘0’. Thus, the inventive concept minimizes or reduces leakage current caused by a low energy band barrier.

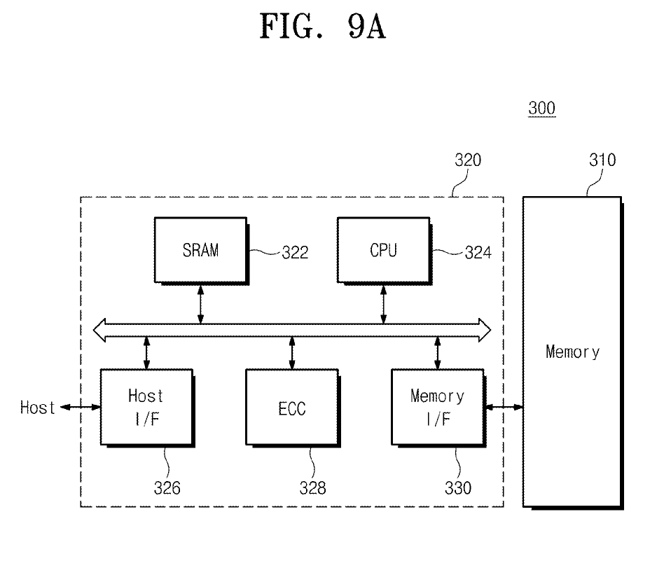

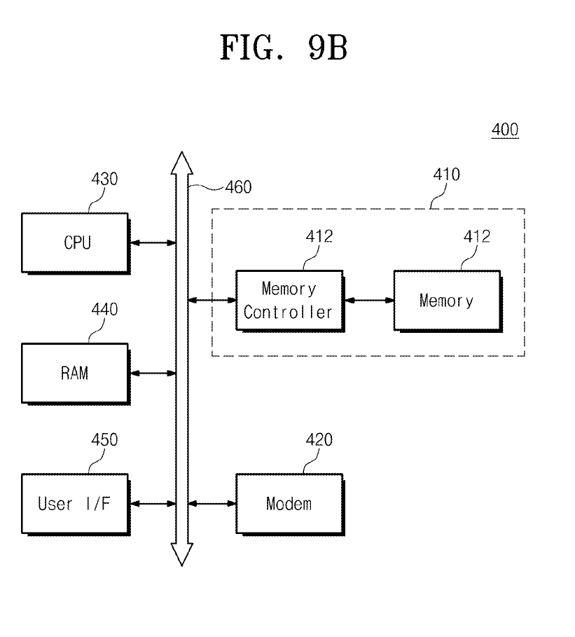

FIG. 9A illustrates a memory card including a semiconductor device(s) according to the inventive concept.

Referring to FIG. 9A, this example of such a memory card 300 includes a memory controller 320 that controls data communication between a host and a memory device 310. A static random access memory (SRAM) device 322 may be used as an operation memory of a central processing unit (CPU) 324. A host interface unit 326 is configured to provide a protocol for data communication between the memory card 300 and the host. An error check and correction (ECC) block 328 detects and correct errors of data which are read out from the memory device 310. A memory interface unit 330 provides an interface between the memory device 310 and the memory controller 320. The CPU 324 controls overall operations of the memory controller 324.

FIG. 9B illustrates an information processing system having a semiconductor device(s) according to the inventive concept.

Referring to FIG. 9B, this example of such an information processing system 400 constitutes a mobile device or a computer. To this end, for example, the information processing system 400 may include a modem 420, a central processing unit (CPU) 430, a random access memory (RAM) 440, and a user interface unit 450 that are electrically connected to a memory system 410 through a system bus 460. The memory system 410 may store data processed by the CPU 430 or data inputted from an external system. The memory system 410 may include a memory device 412 and a memory controller 414. The memory system 410 may have substantially the same structure as the memory card 300 described with reference to FIG. 9A. The information processing system 400 may be embodied as a memory card, a solid state drive (SSD) device, a camera image sensor, or as any type of application chipset. Such an information processing system 400 in which the memory system 410 is realized as an SSD device can stably and reliably store massive amounts of data.

According to an aspect of the inventive concept as described above, the device isolation pattern has an electrically negative property and a physically tensile property. Thus, the body effect of a transistor provided at an active region defined by the device isolation is relatively great so as to provide a relatively high charge barrier, and has an enhanced on-current characteristic.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A semiconductor device comprising:
a substrate; and
a device isolation pattern extending from a surface of the substrate into the substrate,
wherein the device isolation pattern is net electrically negative, and there is net stress in the device isolation pattern that is tensile.

2. The semiconductor device of claim 1, wherein the device isolation pattern includes silicon oxide, and metal oxide juxtaposed with the silicon oxide.

3. The semiconductor device of claim 2, wherein the metal oxide includes at least one of a hafnium oxide (HfOₓ) layer, an aluminum oxide (AlOₓ) layer, and a zirconium oxide (ZrOₓ) layer.

4. The semiconductor device of claim 2, wherein the silicon oxide layer is in contact with the substrate, and the silicon oxide layer is interposed between the substrate and the metal oxide.

5. The semiconductor device of claim 1, wherein the device isolation pattern defines active regions of the substrate, and
the semiconductor device further comprises:
a gate electrode crossing the active regions and the device isolation pattern;
a gate insulating layer interposed between the gate electrode and the active regions; and
first and second regions of dopant in each of the active regions at both sides of the gate electrode.

6. The semiconductor device of claim 5, wherein the gate electrode extends within the active regions and the device isolation pattern, and the height of the gate electrode in the active regions is greater than the height of the gate electrode in the device isolation pattern, the height being the distance between uppermost and lowermost surfaces of the gate electrode.

7. A semiconductor device comprising:
a substrate comprising semiconductor material;
a device isolation pattern extending in the substrate and delimiting at least one active region of the semiconductor material; and
a transistor situated at the active region, the transistor having a channel region constituted by part of the active region, and
wherein there is net stress in the device isolation pattern that is tensile, net stress in the active region that is compressive, and the device isolation pattern is net electrically negative.

8. The semiconductor device of claim 7, wherein the device isolation pattern comprises silicon oxide in contact with the active region.

9. The semiconductor device of claim 8, wherein the device isolation pattern also comprises material that is electrically negative, and the silicon oxide is interposed between the electrically negative material and the active region.

10. The semiconductor device of claim 9, wherein there is tensile stress in the material that is electrically negative and greater than tensile stress in the silicon oxide.

11. The semiconductor device of claim 9, wherein the electrically negative material comprises at least one metal oxide.

12. The semiconductor device of claim 11, wherein the electrically negative material comprises at least one of a hafnium oxide (HfOₓ) layer, an aluminum oxide (AlOₓ) layer, and a zirconium oxide (ZrOₓ) layer.

13. The semiconductor device of claim 7, wherein the transistor includes a gate electrode extending within and across the active region and within the device isolation pattern and a gate insulating layer interposed between the gate electrode and the active region, and the height of the gate electrode in the active region is greater than the height of the gate electrode in the device isolation pattern, the height being the distance between uppermost and lowermost surfaces of the gate electrode.

14. The semiconductor device of claim 13, wherein the substrate has doped regions on opposite sides of the gate electrode and which are source and drain regions of the transistor, respectively.

15. A method of manufacturing a semiconductor device, the method comprising:
forming a trench in a substrate;
conformally forming silicon oxide on the substrate including along surfaces defining the trench, whereby a portion of the trench remains unfilled; and
forming metal oxide in said portion of the trench that remains unfilled after the silicon oxide has been formed, thereby forming a device isolation pattern.

16. The method of claim 15, wherein the forming of the silicon oxide comprises forming a layer of silicon oxide by an atomic layer deposition (ALD) process.

17. The method of claim 15, wherein the forming of the silicon oxide comprises:
forming a first silicon oxide layer on the substrate by a radical oxidation process; and
forming a second silicon oxide layer on the first silicon oxide layer by a low-pressure deposition process.

18. The method of claim 15, wherein the forming of the metal oxide comprises forming at least one layer of metal oxide by an atomic layer deposition (ALD) process.

19. The method of claim 15, wherein the device isolation pattern defines active regions,
the method further comprising:
etching the active regions and the device isolation pattern to form a recess;
forming a gate insulating layer along surfaces defining the recess;
forming a gate electrode in a lower region of the recess after the gate insulating layer has been formed;
forming a capping pattern in an upper region of the recess and such that the capping pattern is disposed on the gate electrode; and
doping the active region at both sides of the gate electrode to form first and second dopant regions.

20. The method of claim 19, wherein the forming of the recess comprises forming the recess in the active regions to a depth less than that to which the recess is formed in the device isolation pattern, whereby the recess is shallower in the active region than it is in the device isolation pattern.
